(19) United States
(12) Patent Application Publication
(10) Pub. No.: US 2020/0332428 A1
(43) Pub. Date: Oct. 22, 2020

(54) METHOD FOR MANUFACTURING COPPER FOIL FOR HIGH FREQUENCY CIRCUIT

(71) Applicant: Industrial Technology Research Institute, Hsinchu (TW)

(72) Inventors: Jhen-Rong Chen, Taoyuan City (TW); Chiu-Yen Chiu, Hsinchu County (TW)

(73) Assignee: Industrial Technology Research Institute, Hsinchu (TW)

(21) Appl. No.: 16/917,914

(22) Filed: Jul. 1, 2020

Related U.S. Application Data
(62) Division of application No. 15/943,735, filed on Apr. 3, 2018.

(30) Foreign Application Priority Data
Nov. 15, 2017 (TW) 106139522

(51) Int. Cl. C25D 1/04; C25D 5/12; C25D 7/06; C25D 5/48; H05K 1/02; H05K 1/09

(52) U.S. Cl. CPC C25D 1/04; C25D 5/12; C25D 7/0614; C25D 3/38; H05K 1/0237; H05K 1/09; C25D 5/48

(57) ABSTRACT

A method of manufacturing a copper foil for a high frequency circuit includes sequentially forming a fine roughness copper nodule layer on a surface of an electroplated copper layer, the fine roughness copper nodule layer being consisted essentially of copper particles or copper alloy particles with a particle size of 100 nm to 200 nm; then, performing electroplating with a Zn—Ni co-electroplating formula for 3 seconds or more to form a Zn—Ni plating layer on the fine roughness copper nodule layer, the Zn—Ni plating layer including 90-150 μg/dm² of zinc and 75-120 μg/dm² of nickel; forming a rust-proof layer on the Zn—Ni plating layer, the rust-proof layer including 20-40 μg/dm² of chromium; and next, forming a hydrophobic layer on the rust-proof layer, the hydrophobic layer having a water contact angle of 80 to 150 degrees.

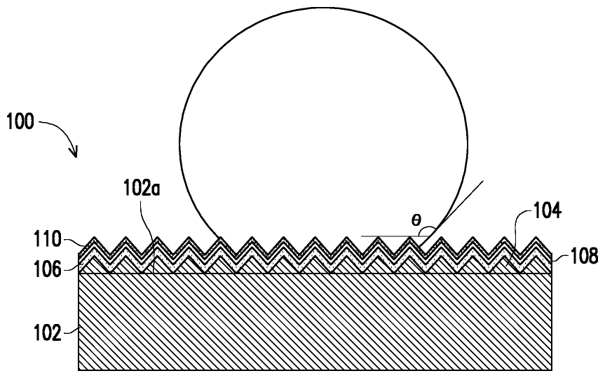

### CROSS-REFERENCE TO RELATED APPLICATION

This application is a divisional application of and claims the priority benefit of U.S. patent application Ser. No. 15/943,735, filed on Apr. 3, 2018, now pending. The prior application Ser. No. 15/943,735 claims the priority benefit of Taiwan application serial no. 106139522, filed on Nov. 15, 2017. The entirety of each of the above-mentioned patent applications is hereby incorporated by reference herein and made a part of this specification.

### TECHNICAL FIELD

The disclosure relates to a method of manufacturing a copper foil for a high frequency circuit.

### BACKGROUND

As the demand from applications of high frequency high speed transmission grows, the required specification of PCB materials has also been constantly updated. In terms of substrate materials, the low transmission loss substrate (Df<0.005@10 GHz) is already commercially available. In order to apply on the applications of high frequency high speed transmission, the copper foils for a high frequency circuit have also been constantly improved.

Since the signal transmission line of the PCB is formed of a dielectric material and a metal conductor, insertion loss generated in transmission is also collectively contributed by the dielectric material and the conductor. The loss contributed by the metal conductor has to be decreased by reducing the surface resistance of the metal conductor. When a transmission frequency of a signal is increased, the current is prone to aggregate on the conductor surface, and this phenomenon is called the skin effect. Even if the conductor surface is smooth, a reduction in a cross-sectional area through which a current signal passes may still cause the surface resistance increasing, which thereby increases the loss in signal transmission. For example, at a transmission frequency of 1 GHz, a conductor skin depth is 2 μm, but at 10 GHz, the skin depth is only 0.66 μm.

Considering that the reduction in the cross-sectional area through which the current signal passes increases the surface resistance, the bonding surfaces of the copper foil and the substrate material are generally specifically treated to enhance bonding with the substrate, and thus the conductor surface is roughened, which further increases the surface resistance and significantly affects electrical performance.

Therefore, there is a need to develop a copper foil that not only maintains the bonding with the substrate but also reduces the transmission loss.

### SUMMARY

A method of manufacturing a copper foil for a high frequency circuit according to an embodiment of the disclosure includes sequentially forming a fine roughness copper nodule layer on a surface of an electroplated copper layer, the fine roughness copper nodule layer being consisted essentially of copper particles or copper alloy particles with a particle size of 100 nm to 200 nm; then, performing electroplating with a Zn—Ni co-electroplating formula for 3 seconds or more to form a Zn—Ni plating layer on the fine roughness copper nodule layer, the Zn—Ni plating layer including 90-150 μg/dm² of zinc and 75-120 μg/dm² of nickel; forming a rust-proof layer on the Zn—Ni plating layer, the rust-proof layer including 20-40 μg/dm² of chromium; and next, forming a hydrophobic layer on the rust-proof layer, the hydrophobic layer having a water contact angle of 80 to 150 degrees.

Several exemplary embodiments accompanied with FIGURE are described in detail below to further describe the disclosure in details.

### BRIEF DESCRIPTION OF THE DRAWINGS

The FIGURE is a schematic diagram illustrating a copper foil for a high frequency circuit according to an embodiment of the disclosure.

### DETAILED DESCRIPTION OF DISCLOSED EMBODIMENTS

Referring to the embodiments below and the accompanied drawings for a detailed description of the disclosure. However, the provided embodiments are not meant to limit the scope covered by the disclosure. Moreover, the drawings are merely illustrative and are not drafted according to the actual dimensions. Different layers may be enlarged or reduced to be presented in the same drawing.

The FIGURE is a schematic diagram illustrating a copper foil for a high frequency circuit according to an embodiment of the disclosure.

Referring to The FIGURE, a copper foil 100 for a high frequency circuit of the present embodiment has a roughness sRq of 0.1 μm to 0.5 μm, and the copper foil 100 for a high frequency circuit includes an electroplated copper layer 102, a fine roughness copper nodule layer 104 located on a surface 102a of the electroplated copper layer 102, a Zn—Ni plating layer 106 located on the fine roughness copper nodule layer 104, a rust-proof layer 108 located on the Zn—Ni plating layer 106, and a hydrophobic layer 110 located on the rust-proof layer 108.

The fine roughness copper nodule layer 104 is consisted essentially of copper particles or copper alloy particles with a particle size of 100 nm to 200 nm, and the copper alloy is formed of copper and elements selected from a group consisting of cobalt (Co), nickel (Ni), iron (Fe), and molybdenum (Mo), such as Cu—Fe—Mo and Cu—Co—Ni. From the perspective of inhibiting growth of the copper alloy particles, the material of the copper alloy particles may include molybdenum. Since the particle size of the fine roughness copper nodule layer 104 is merely 100 nm or so, bonding between the copper foil 100 for a high frequency circuit and a high frequency resin substrate material (not illustrated) is significantly enhanced, which further reduces a content of non-copper elements plated in a subsequent process and also ensures electrical performance. The Zn—Ni plating layer 106 includes 90-150 μg/dm² of zinc and 75-120 μg/dm² of nickel. In an embodiment, the Zn—Ni plating layer 106 includes 90-130 μg/dm² of zinc and 75-105 μg/dm² of nickel. The rust-proof layer 108 includes 20-40 μg/dm² of chromium. The hydrophobic layer 110 has a water contact angle θ of 80 to 150 degrees. In an embodiment, the hydrophobic layer 110 is selected from a group consisting of materials derived from organosilane, such as vinyl silane, epoxy silane, and amino silane. In an embodiment, the vinyl silane is (but is not limited to) vinyltrimethoxysilane or vinyltriethoxysilane, for example. The epoxy silane is (but is not limited to) epoxy functional methoxysilane, for example. The amino silane is selected from (but is not limited to) (3-trimethoxysilylpropyl)ethylenediamine, (3-triethoxysilylpropyl)ethylenediamine, (3-aminopropyl)trimethoxysilane, or (3-aminopropyl)triethoxysilane, for example.

Moreover, since thicknesses of each layer are extremely small, content ranges of each component are obtained by analyzing a surface composition. In other words, the foregoing element content ranges and ratios of each layer are obtained by analyzing the surface composition. In an embodiment, a weight ratio of nickel of the Zn—Ni plating layer 106 to silicon of the hydrophobic layer 110 (i.e., a Ni/Si weight ratio) is 1.8 to 4.5. A weight ratio of zinc of the Zn—Ni plating layer 106 to silicon of the hydrophobic layer 110 (i.e., a Zn/Si weight ratio) is 2.2 to 5.5. If the Zn/Si value is 5.5 or smaller, heat resistance is not only enhanced, but acid resistance of the copper foil is also maintained; if the Zn/Si value is 2.2 or greater, heat resistance is exhibited. If the Ni/Si value is 4.5 or smaller, a surface resistance is not increased, and it is favorable to perform an etching process; if the Ni/Si value is 1.8 or greater, acid resistance and heat resistance are exhibited. If the Cr/Si value is 1.6 or smaller, an increase in the surface resistance is small while surface oxidation resistance is increased, and it is favorable for high frequency transmission; if the Cr/Si value is 0.5 or greater, oxidation resistance is exhibited.

In the text below, experimental examples are provided to verify the effect of the embodiments of the disclosure, but the disclosure is not limited to the description below.

### Experimental Example 1

A raw foil (electroplated copper layer) with Rz<1.5 μm was provided, and a surface of the raw foil was treated by an ultra-fine surface roughening process to form a fine roughness copper nodule layer. The ultra-fine surface roughening process was based on a low-copper content copper sulfate-based solution, to which Fe and Mo were added as inhibitors in the ultra-fine surface roughening process (a formula of the fine roughness solution was Cu: 2 g/L, sulfuric acid: 90 g/L, Fe: 100 ppm, Mo: 400 ppm), such that a size of particles formed on the surface was uniform and thin. Moreover, electroplating conditions were controlled to bond the formed particles to the surface of the electroplated copper layer. The electroplating conditions are: nucleation current density: 6 A/dm², covering current density: 1.2 A/dm², bonding electroplating condition: 0.5 A/dm². The electroplating process is: performing nucleation electroplating for 3 seconds, and then performing covering electroplating for 5 seconds. After this process was cycled twice, bonding electroplating was performed for 10 seconds, and the fine roughness copper nodule layer having a surface covered by copper nodules with a particle size of 100 nm to 200 nm was obtained.

Next, electroplating was performed on the fine roughness copper nodule layer with a Zn—Ni co-electroplating formula for 4 seconds (the co-electroplating formula is Zn: 2 g/L, Ni: 0.75 g/L, potassium pyrophosphate: 60 g/L), then the electroplated fine roughness copper nodule layer was impregnated in a chromic acid solution for about 10 to 15 seconds, and finally a N-(2-aminoethyl)-3-aminopropyltrimethoxysilane (KBM-603) solution was sprayed thereto, wherein the organosilane solution concentration was 0.5 vol %. After spraying, the product was completed after being oven-dried at 105° C. for 5 minutes.

### Experimental Example 2

The same preparation method as Experimental Example 1 was adopted, but the organosilane used was replaced with 3-aminopropyltriethoxysilane (KBE-903).

### Experimental Example 3

The same preparation method as Experimental Example 1 was adopted, but the organosilane used was replaced with vinyltrimethoxysilane (KBM-1003).

### Comparative Example 1

The same preparation method as Experimental Example 1 was adopted, but the organosilane spraying step was omitted, and the product was directly oven-dried at 105° C. for 5 minutes.

The copper foil products of Experimental Examples 1 to 3 and Comparative Example 1 respectively underwent a measurement of water contact angle and a peel strength test which the copper foils mentioned above were boned with the same type of high frequency prepregs. The results are presented in Table 1 below. Specifically, the peel strength was measured after hot pressing process. Moreover, the roughness sRq of the copper foil products of Experimental Examples 1 to 3 and Comparative Example 1 were measured by a white light interferometry (in accordance with the ISO25178 standard), and the results are presented in Table 1 below.

TABLE 1

| | Experimental | Experimental | Experimental | Comparative |
|---|---|---|---|---|
| | Example 1 | Example 2 | Example 3 | Example 1 |
| Water | 82.7 | 93.1 | 145 | 11.2 |
| contact angle | | | | |
| (degree) | | | | |
| Peel strength | 0.38 | 0.67 | 0.66 | 0.3 |
| (kg/cm) | | | | |
| sRq (μm) | 0.22 | 0.22 | 0.22 | 0.22 |

According to Table 1, the organosilane-treated surfaces (having a hydrophobic layer) had water contact angles greater than that of the surface without the organosilane treatment and exhibited more desirable peel strengths.

### Experimental Example 4

The same method as Experimental Example 2 was adopted, but electroplating was performed with the Zn—Ni co-electroplating formula for 3 seconds.

### Experimental Example 5

The same method as Experimental Example 2 was adopted, but electroplating was performed with the Zn—Ni co-electroplating formula for 5 seconds.

Surface compositions of the copper foil products of Experimental Example 2 and Experimental Examples 4 to 5 were respectively analyzed, and the results are presented in Table 2 below.

TABLE 2

| | Experimental | Experimental | Experimental |
|---|---|---|---|
| Component | Example 4 | Example 2 | Example 5 |
| (μg/dm²) | (3 seconds) | (4 seconds) | (5 seconds) |
| Zn | 90-100 | 120-130 | 140-150 |
| Ni | 75-90 | 95-105 | 110-120 |
| Mo | 18-25 | 18-25 | 18-25 |
| Cr | 20-40 | 20-40 | 20-40 |
| Si | 30-40 | 30-40 | 30-40 |

According to Table 2, content ranges of components in the cases of electroplating for 3 to 5 seconds were, for example, 90-150 μg/dm² of zinc, 75-120 μg/dm² of nickel, and 20-40 μg/dm² of chromium.

### Experimental Example 6

The same method as Experimental Example 2 was adopted, but the Zn—Ni co-electroplating time was altered, and the subsequent chromic acid and organosilane treatments were both identical (0.5 vol % of KBE-903). Peel strength variations after tests of acid resistance (impregnated in 18% HCl for 1 hour) and boiling water resistance (impregnated in boiling water for 2 hours) are presented in Table 3.

TABLE 3

| | 0 | 2 | 3 | 5 |
|---|---|---|---|---|
| | seconds | seconds | seconds | seconds |
| As-received peel strength (kg/cm) | 0.6 | 0.63 | 0.67 | 0.67 |
| Peel strength after acid resistance | 0.4 | 0.5 | 0.67 | 0.67 |
| test (kg/cm) | | | | |
| Peel strength after boiling | 0.35 | 0.45 | 0.67 | 0.67 |
| water resistance test (kg/cm) | | | | |

According to Table 3, the copper foils undergoing the ultra-fine surface roughening process and the Zn—Ni co-electroplating for 3 seconds or more (namely, the copper foil surface included 90-150 μg/dm² of zinc, 75-120 μg/dm² of nickel, and 20-40 μg/dm² of chromium) all passed the acid resistance and boiling water resistance tests. The copper foils of which the surface zinc content was less than 90 μg/dm², the nickel content was less than 75 μg/dm², and the chromium content was less than 20 μg/dm² had peel strengths reduced to 0.6 kg/cm or less after the acid resistance and boiling water resistance tests due to insufficient acid resistance and heat resistance.

In summary of the above, in the embodiments of the disclosure, the fine roughness copper nodule layer with a small particle size is manufactured on the copper foil surface by using the ultra-fine surface roughening technique. The fine roughness copper nodule layer along with the specific Zn—Ni plating layer, rust-proof layer, and hydrophobic layer together form the copper foil for a high frequency circuit having a small surface roughness and a low surface alloying element content, which exhibits excellent bonding with the high frequency substrate material and is favorable for high frequency transmission.

Although the embodiments are already disclosed as above, these embodiments should not be construed as limitations on the scope of the disclosure. It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A method of manufacturing a copper foil for a high frequency circuit, comprising:
forming a fine roughness copper nodule layer on a surface of an electroplated copper layer, the fine roughness copper nodule layer being consisted essentially of copper particles or copper alloy particles with a particle size of 100 nm to 200 nm;
performing electroplating with a Zn—Ni co-electroplating formula for 3 seconds or more to form a Zn—Ni plating layer on the fine roughness copper nodule layer, the Zn—Ni plating layer comprising 90-150 μg/dm² of zinc and 75-120 μg/dm² of nickel;
forming a rust-proof layer on the Zn—Ni plating layer, the rust-proof layer comprising 20-40 μg/dm² of chromium; and
forming a hydrophobic layer on the rust-proof layer, the hydrophobic layer having a water contact angle of 80 to 150 degrees.

2. The method of manufacturing a copper foil for a high frequency circuit according to claim 1, wherein the Zn—Ni co-electroplating formula comprises zinc, nickel, and potassium pyrophosphate.

3. The method of manufacturing a copper foil for a high frequency circuit according to claim 1, wherein a duration of the electroplating for forming the Zn—Ni plating layer is 3 to 5 seconds.

4. The method of manufacturing a copper foil for a high frequency circuit according to claim 1, wherein an organosilane solution for forming the hydrophobic layer comprises vinyl silane, epoxy silane, or amino silane.

5. The method of manufacturing a copper foil for a high frequency circuit according to claim 4, wherein the amino silane comprises: (3-trimethoxysilylpropyl)ethylenediamine, (3-triethoxysilylpropyl)ethylenediamine, (3-aminopropyl)trimethoxysilane, or (3-aminopropyl)triethoxysilane.

6. The method of manufacturing a copper foil for a high frequency circuit according to claim 4, wherein the vinyl silane comprises: vinyltrimethoxysilane or vinyltriethoxysilane.

7. The method of manufacturing a copper foil for a high frequency circuit according to claim 1, wherein the copper alloy particles are formed of copper and elements selected from a group consisting of Fe, and Mo.

8. The method of manufacturing a copper foil for a high frequency circuit according to claim 1, wherein a step of forming the fine roughness copper nodule layer comprises treating the surface of the electroplated copper layer by an ultra-fine surface roughening process.

9. The method of manufacturing a copper foil for a high frequency circuit according to claim 8, wherein a solution used in the ultra-fine surface roughening process comprises a copper sulfate-based solution with Fe and Mo added as inhibitors in the ultra-fine surface roughening process.

10. The method of manufacturing a copper foil for a high frequency circuit according to claim 8, wherein the ultra-fine surface roughening process comprises performing an nucleation electroplating and then performing a covering electroplating.

11. The method of manufacturing a copper foil for a high frequency circuit according to claim 10, further comprising performing a bonding electroplating after cycling twice of the nucleation electroplating and the covering electroplating.

12. The method of manufacturing a copper foil for a high frequency circuit according to claim 1, wherein a step of forming the rust-proof layer comprises impregnating the Zn—Ni plating layer in a chromic acid solution.

13. The method of manufacturing a copper foil for a high frequency circuit according to claim 12, wherein a duration of the impregnating for forming the rust-proof layer is 10 to 15 seconds.
